(19) United States
(12) Patent Application Publication
(10) Pub. No.: US 2010/0012180 A1
(43) Pub. Date: Jan. 21, 2010

(54) ENCAPSULATING AND TRANSFERRING LOW DIMENSIONAL STRUCTURES

(75) Inventors: Stephen Day, Oxfordshire (GB); Thomas Heinz-Helmut Altebaeumer, Oxfordshire (DE); Jonathan Heffernan, Oxfordshire (IE)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(73) Assignee: SHARP KABUSHIKI KAISHA, Osaka (JP)

(21) Appl. No.: 12/444,875

(22) PCT Filed: Oct. 11, 2007
(86) PCT No.: PCT/JP2007/070299

§ 371 Date: May 6, 2009

(30) Foreign Application Priority Data
Oct. 11, 2006 (GB) 0620134.7

(51) Int. Cl. H01L 31/0203; B29B 13/00; B32B 3/20

(52) U.S. Cl. 136/256; 264/271.1; 264/275; 428/188

(57) ABSTRACT

A method of encapsulating low dimensional structures comprises forming a first group (3a) of low dimensional structures (1) and a second group (3b) of low dimensional structures (1) on a first substrate. The first group (3a) of low dimensional structures (1) and the second group (3b) of low dimensional structures (1) are encapsulated in a matrix (5), with the first group (3a) of low dimensional structures (1) being encapsulated separately from the second group (3b) of low dimensional structures (1). After encapsulation, the first group (3a) of low dimensional structures (1) may be separated from the second group (3b) of low dimensional structures (1). Each group may then be processed, for example by transfer to a second substrate (7). The number of low dimensional structures in a group, and the aspect ratio of a group is defined when the low dimensional structures are formed, and can therefore be controlled more accurately than in a conventional method in which groups are defined using a patterning technique.

### TECHNICAL FIELD

The present invention relates to the encapsulation of micro- and nano-sized low dimensional structures including, but not limited to, structures with an elongate geometry, for example to allow their transfer from a donor substrate to a receiver substrate or to allow their re-orientation on a substrate.

The term “low dimensional structure” as used herein refers to a structure that has at least one dimension that is much less than at least a second dimension.

The term “elongate structure” as used herein refers to a structure having at least two dimensions that are much less than a third dimension. The definition of an “elongate structure” lies within the definition of a “low dimensional structure”, and a nanowire is an example of a structure that is both a low dimensional structure and an elongate structure.

### BACKGROUND ART

Low dimensional structures that are not elongate structures are known. For example, a ‘platelet’, which has two dimensions of comparable magnitude to one another and a third (thickness) dimension that is much less than the first two dimensions constitutes a “low dimensional structure” but is not an “elongate structure”.

It is often desirable to be able to form low dimensional structures such as, for example, nanowires or carbon nanotubes, on a first substrate (a ‘formation/donor substrate’) and to transfer them to a second substrate (a ‘target/receiver substrate’). For example, a target substrate (for example, a glass substrate) may have some property desirable for the final device, but may not be compatible with the processes necessary to form the low dimensional structures—in such as case, it is necessary to form the low dimensional structures on a formation substrate (for example a silicon substrate) that is compatible with the processes necessary to form the low dimensional structures, and subsequently transfer the low dimensional structures to the target substrate (depending on the exact processes required, the low dimensional structures may be transferred direct from the formation substrate to the target substrate or they may be transferred from the formation substrate via one or more intermediate substrates to the target substrate).

In other cases it may be possible to form the low dimensional structures on the target substrate, but not in the desired orientation. In such cases the low dimensional structures are formed on the target substrate in an orientation compatible with the formation process, and are then re-oriented to an orientation suitable, for example, for their use in a finished device.

Where low dimensional structures are formed on a formation substrate and are transferred to a target substrate, or are formed on a target substrate but require to be re-oriented, it is desirable to be able to exercise a degree of control over the arrangement of the low dimensional structures on the target substrate after transfer/re-orientation, both with respect to predefined features on the target substrate and with respect to other transferred/re-oriented low dimensional structures.

In many cases it is desirable that the alignment, orientation, and spatial arrangement of the low dimensional structures relative to one another, as formed on the formation substrate, are preserved when the low dimensional structures are transferred to the target substrate. However, it may be desired to re-orient the low dimensional structures relative to another object when the low dimensional structures are transferred. The reorientation could be a separate step prior to transfer or part of the transfer step/process itself, or it could be done after transfer is complete. For example, in the case of elongate low dimensional structures it is often desirable to be able to form the elongate structures with their longitudinal axes oriented perpendicular to the formation substrate, since this provides better control of the formation process. However, in many cases it is also desirable that the elongate structures should have their longitudinal axes oriented parallel with respect to the plane of the target substrate—for example, this makes it easier to make electrical contacts to the elongate structures. In such a case, it is desirable to re-orient the elongate structures when they are transferred from the formation substrate to the target substrate.

Methods are known for transferring structural features from a first to a second substrate. However, at present there are few suitable technique for applying a high density of structural features with an elongate/low dimensional geometry to a receiver substrate such that one or more of the following desiderata are met:

(a) the elongate/low dimensional structures are oriented with a common direction, for example the longitudinal axes of elongate structures are oriented with a common direction;

(b) the spatial arrangement and spacing of the elongate/low dimensional structures can be substantially controlled;

(c) at least one edge of the elongate/low dimensional structures is aligned with one or more common planes;

(d) the elongate/low dimensional structures can be transferred with high yield—that is, the number of defects due to missing, mis-aligned or interstitial structures is minimised; and

(e) the orientation of the elongate/low dimensional structures can be changed during the transfer.

Control over one or more (and preferably all) the factors set out above is necessary to permit the use of such elongate or low dimensional structures to improve existing and develop new nanotechnologies.

U.S. Pat. No. 7,067,328 discloses a method for transferring nanowires from a donor substrate (for example the substrate on which they are formed) to a receiver substrate. This is achieved by disposing an adhesion layer on the receiver substrate, and mating it with the donor substrate. A degree of alignment and ordering of the nanowires on the receiver substrate is achieved by moving the donor substrate and receiver substrate relative to one another while they are in contact.

U.S. Pat. No. 6,872,645 teaches a method of positioning and orienting elongate nanostructures on a surface by harvesting them from a first substrate into a liquid solution and then flowing the solution along fluidic channels formed between a second substrate and an elastomer stamp. The nanostructures adhere to the second substrate from the solution with a preferred orientation corresponding to the direction of fluid flow.

U.S. Pat. No. 7,091,120 discloses a process in which a liquid material is disposed on a population of nanowires that are attached to a first substrate with their longitudinal axes perpendicular to the plane of the first substrate. The material is then processed in order to cause it to solidify into a matrix that is designed to adhere to the nanowires and act as a support for the nanowires during the process of separating the nanowires from a first substrate and transferring them to a second substrate. Optionally, once the composite of nanowires embedded in the matrix material has been successfully transferred to the second substrate the matrix material can be removed to leave only the nanowires.

U.S. Pat. No. 7,091,120 also discloses an extension to this process whereby the composite of nanowires embedded in the matrix material is lithographically patterned into blocks. The blocks are then applied to a second substrate such that the embedded nanowires are aligned with their longitudinal axes parallel to the plane of the second substrate.

In one embodiment of the method of U.S. Pat. No. 7,091,120 the composite material is formed by unidirectionally disposing the matrix material on an ordered or random arrangement of nanowires. The directional flow of the matrix material induces the nanowires to orientate within the composite material parallel to the plane of the first substrate.

The method of U.S. Pat. No. 7,091,120 has a number of disadvantages, as follows:

In U.S. Pat. No. 7,091,120 the matrix material is deposited as a liquid material or precursor (e.g. a polymer solution or spin-on-glass). This restricts the range of materials that can be used to those that traditionally exhibit poor electrical performance and/or degradation/aging and temperature stability, thereby limiting the functionality and performance of the matrix.

Deposition of the matrix as a liquid may disturb the alignment/orientation of the elongated nanostructures on the donor substrate. Hence, it is challenging to control the arrangement and/or orientation of the elongated structures contained in each block relative to the external dimensions of the block.

Patterning the matrix is wasteful, as some elongate structures are inevitably lost in the patterning step—the method of U.S. Pat. No. 7,091,120 is subtractive, in that the method requires removal of material that has previously been grown;

The absolute dimensions and aspect ratio of the composite blocks are limited by the resolution, alignment accuracy and anisotropy of the lithographic and etch processes used to pattern the blocks (generally, only blocks with a low aspect ratio can be obtained). Consequently, it is difficult to control the number of elongated structures contained in each block or, again, the arrangement of elongated structures contained in each block relative to the external dimensions of the block.

The method results in a large contact area between a block and the donor substrate, such that there is an undesirable level of adhesion between the two. This makes separation of the two difficult.

The method does not easily enable nanostructures to be reoriented from a perpendicular orientation relative to the first substrate to a parallel orientation relative to the second substrate.

US patent application No. 2004/0079278 discloses a method of forming a composite material comprising an array of isolated nanowires and a matrix that fills in the gaps between the materials. This method is designed to fabricate monolithic photonic band gap composite structures that cannot easily be transferred between different substrates.

U.S. Pat. No. 7,068,898 discloses a composite structure comprising nanostructures dispersed in a polymer matrix with random and ‘less random’ orientations. The application is directed to light concentrators and waveguides that take advantage of the anisotropic emission pattern to ensure light is redirected in the guide or concentrator as desired.

US patent application No. 2005/0219788 relates to a capacitor having nanostructures provided on one plate of the capacitor, in order to increase the effective area of the plate. An insulating layer is disposed over the plate and over the nanostructures, and a second plate is then deposited over the insulating layer.

WO 2005/119753 relates to growing nanowires, and suggests that nanowires may be encapsulated in a polymer.

### DISCLOSURE OF INVENTION

A first aspect of the present invention provides a method of encapsulating low dimensional structures, the method comprising: forming a first group of low dimensional structures and a second group of low dimensional structures on a first substrate; and encapsulating the first group of low dimensional structures and the second group of low dimensional structures in a matrix, the first group of low dimensional structures being encapsulated separately from the second group of low dimensional structures.

By specifying that the two groups of low dimensional structures are encapsulated “separately” is meant that, even after encapsulation, the first group of low dimensional structures is distinguishable from the second group of elongate structures.

For the avoidance of doubt, specifying that the two groups of low dimensional structures are encapsulated “separately” does not require that the first group of low dimensional structures is encapsulated at a different time, or in a different process step, from the second group of low dimensional structures.

In the method, the groups of low dimensional structures are defined when the low dimensional structures are formed over the formation substrate. For example, a suitable catalyst may be disposed on the formation substrate at each location where it is desired to form a low dimensional structure, so that the groups are defined by the locations where the catalyst is disposed on the formation substrate. It is therefore not necessary to encapsulate a large number of low dimensional structures and pattern the matrix by removal of some material, so that the waste inherent in the method of U.S. Pat. No. 7,091,120 is eliminated.

The number of low dimensional structures in the matrix is defined when the low dimensional structures are formed, rather than when the matrix is patterned by removal of material as in the method of U.S. Pat. No. 7,091,120. The precision with which groups of low dimensional structures may be formed on the formation substrate is much greater than the precision with which the matrix may be patterned in U.S. Pat. No. 7,091,120, so that the invention allows much greater control of the number of low dimensional structures in the matrix. Moreover, a group of low dimensional structures of the invention may have a very large aspect ratio, for example up to 500:1 or 1000:1, whereas the blocks obtained by the patterning process of U.S. Pat. No. 7,091,120 will have a very low aspect ratio.

The low dimensional structures may be encapsulated such that the matrix encapsulating the first group of low dimensional structures is continuous with the matrix encapsulating the second group of low dimensional structures only near the formation substrate. This may be the case, for example, where process of formation of the matrix is relatively unselective, so that a matrix is formed over the entire area of the first substrate. In this embodiment, the thickness of the matrix formed between the first group and the second group is arranged to be different from the thickness of the encapsulated groups of low dimensional structures, so that the first group of low dimensional structures is, even after encapsulation, distinguishable from the second group of low dimensional structures.

Alternatively, the low dimensional structures may be encapsulated such that the matrix encapsulating the first group of low dimensional structures is not continuous with the matrix encapsulating the second group of low dimensional structures. This may be the case, for example, where process of formation of the matrix is selective, so that a matrix is formed only over the low dimensional structures.

The method may comprise the further step of separating the matrix encapsulating the first group of low dimensional structures from the matrix encapsulating the second group of low dimensional structures.

The method may comprise the further step of transferring at least one of the first group of low dimensional structures and the second group of low dimensional structures to a second substrate.

The spacing between the first group and the second group may be greater than the maximum spacing between adjacent low dimensional structures in any of the groups.

The low dimensional structures in each group may be arranged along a respective line.

The low dimensional structures in each group may be arranged along a respective straight or substantially straight line.

The low dimensional structures in each group may be regularly spaced, or they may be irregularly spaced.

The method may further comprise the steps of: forming a layer over the first substrate; and defining a plurality of holes in the layer so as to expose the first substrate; and the step of forming the first and second groups of low dimensional structures may comprise forming each structure at a respective hole in the layer.

The method may comprise the further step of removing the layer after forming the first and second groups of low dimensional structures.

A second aspect of the present invention provides a method comprising: forming a layer over a substrate; defining a plurality of holes in the layer; forming a plurality of low dimensional structures over the substrate, each structure at a respective hole in the layer; encapsulating the low dimensional structures in a matrix; and removing the layer.

The method may comprise the further step of transferring the low dimensional structures to a second substrate.

The layer may be a silica or silicon nitride layer.

The method may comprise the further step of removing at least a portion of the matrix.

The step of removing at least a portion of the matrix may comprise planarising at least one surface of the matrix.

The step of removing at least a portion of the matrix may comprise exposing at least a portion of at least one low dimensional structure.

Forming the low dimensional structures on the first substrate may comprise forming the low dimensional structures with a first substantially unidirectional orientation.

Forming the low dimensional structures on the formation substrate may comprise forming elongate structures with their longitudinal axes substantially perpendicular to the first substrate.

The transferring step may comprise transferring the low dimensional structures to the second substrate with a second substantially unidirectional orientation different from the first substantially unidirectional orientation.

The transferring step may comprise transferring the low dimensional structures to the second substrate with their longitudinal axes substantially parallel to the second substrate.

The step of encapsulating the low dimensional structures may comprise forming at least a layer of a first encapsulant material over the elongate structures.

The step of encapsulating the low dimensional structures may comprise forming at least a layer of a first encapsulant material over the elongate structures and forming a layer of a second encapsulant material different from the first encapsulant material over the layer of the first encapsulant material.

The step of encapsulating the low dimensional structures may comprise forming at least a layer of a first encapsulant material over the low dimensional structures, and transforming at least part of the first encapsulant material to a second encapsulant material different from the first encapsulant material.

At least one of the first and second encapsulant materials may be transparent.

At least one of the first and second encapsulant materials may be opaque.

At least one of the first and second encapsulant materials may be electrically insulating.

At least one of the first and second encapsulant materials may be electrically conductive.

At least one of the first and second encapsulant materials may be optically emissive.

At least one of the first and second encapsulant materials may be heterogeneous. By “heterogeneous” is meant that the encapsulant material(s) is not homogeneous, for example, in composition or structure. For example, an encapsulant layer may itself comprise a plurality of ‘guest’ structures (of any size, shape and spatial distribution) made from a first material and encapsulated in a second material. An example of a heterogeneous material would be a silica layer containing a distribution of silicon nanoparticles. Such a composition can be formed by high density plasma CVD process and frequently has luminescent properties. Another example of a heterogeneous material would be a porous material such as, for example, porous anodic alumina.

In general, where a specific property or function of the matrix is referred to, if the matrix comprises two or more encapsulant materials it may be necessary for only one (or, more generally, less than all, if the matrix comprises three or more encapsulant materials) of those materials to provide the function or property referred. For example encapsulant material comprised in the matrix may be electrically insulating while the other (or another) may be electrically conductive.

The method may comprise forming the or each encapsulant material by a substantially isotropic formation process.

The method may comprise forming the or each encapsulant material by a vapour deposition process.

A third aspect of the present invention provides a composite structure comprising: a matrix; and a plurality of low dimensional structures embedded in the matrix; wherein the low dimensional structures are arranged along at least a line extending generally perpendicular to an axis of the low dimensional structures.

The low dimensional structures may be substantially unidirectionally oriented.

The maximum separation between any two adjacent neighbouring low dimensional structures may be less than the smallest dimension of the matrix.

The low dimensional structures may be arranged along a substantially straight line.

The low dimensional structures may be regularly spaced.

The low dimensional structures may be irregularly spaced.

The low dimensional structures may be elongate structures arranged along at least a line extending generally perpendicular to the longitudinal axes of the low dimensional structures.

At least a portion of one or more of the low dimensional structures may be not covered by the matrix.

At least one of the low dimensional structures may be not covered by the matrix along substantially its entire length.

The matrix may comprise at least a layer of a first encapsulant material disposed over each of the low dimensional structures.

The matrix may comprise at least a layer of a first encapsulant material disposed over each of the low dimensional structures and a layer of a second encapsulant material different from the first encapsulant material disposed over the first encapsulant material.

At least one of the first and second encapsulant materials may be transparent.

At least one of the first and second encapsulant materials may be opaque.

At least one of the first and second encapsulant materials may be electrically insulating.

At least one of the first and second encapsulant materials may be electrically conductive.

At least one of the first and second encapsulant materials may be optically emissive.

At least one of the first and second encapsulant materials may be heterogeneous.

The structure may comprise a transistor.

The matrix may encapsulate an intermediate portion of the low dimensional structures but not each end portion of the low dimensional structures; first end portions of the low dimensional structures may be electrically connected to a first electrical contact; second end portions of the low dimensional structures may be electrically connected to a second electrical contact; and the matrix may be electrically connected to a third electrical contact.

The structure may be a light emissive structure.

The structure may comprise means for driving the low-dimensional structures to emit light. It may comprise means for electrically driving the low-dimensional structures to emit light.

The encapsulant material may absorb light, in use, thereby to cause the low-dimensional structures to re-emit light.

The structure may be a light sensing structure.

The structure may be a photo-voltaic structure.

The encapsulant material may be arranged to re-direct incident light onto the low-dimensional structures.

The structure may comprise a memory device.

The matrix may comprise, in sequence: a first electrically insulating layer; a first electrically conductive layer; a second electrically insulating layer; and a second electrically conductive layer; the first electrically insulating layer around a low-dimensional structure may be separate from the first electrically insulating layer around an adjacent low-dimensional structure; the first electrically conductive layer around a low-dimensional structure may be separate from the first electrically conductive layer around an adjacent low-dimensional structure; the second electrically insulating layer around a low-dimensional structure may be continuous with the second electrically insulating layer around an adjacent low-dimensional structure; and the second electrically conductive layer around a low-dimensional structure may be continuous with the second electrically conductive layer around an adjacent low-dimensional structure. This provides a floating gate memory array.

The structure may comprise a first group of low-dimensional structures encapsulated in a first matrix and a second group of low-dimensional structures encapsulated in a second matrix, the first group of low-dimensional structure being opposed to the second group of low dimensional structures; and the first matrix and the second matrix may be electrically conductive. By applying suitable voltages to the two groups of low-dimensional structures it is possible to cause movement of the groups of low-dimensional structures, thereby obtaining a Micro Electro-Mechanical structure.

### BRIEF DESCRIPTION OF DRAWINGS

Preferred embodiments of the present invention will now be described by way of illustrative example with reference to the accompanying figures in which:

FIG. 1 shows a group of low dimensional structures formed on a formation substrate and oriented normal to the plane of the substrate;

FIG. 2 shows another group of low dimensional structures formed on a formation substrate and oriented normal to the plane of the substrate;

FIG. 3 shows the group of low dimensional structures of FIG. 1 encapsulated in a matrix;

FIGS. 4(a) to 4(f) shows steps of one method of the invention;

FIGS. 5(a) to 5(h) shows steps of the encapsulation process of the present invention;

FIGS. 6(a) and 6(b) illustrate steps in the transfer of a group of low dimensional structures to a target substrate;

FIGS. 7(a) to 7(e) shows steps of another method of the invention;

FIG. 7(f) illustrates constraints on the spacing of low dimensional structures according to a method of the invention;

FIG. 8 is a schematic perspective view of a device of the present invention;

FIG. 9 is a schematic perspective view of another device of the present invention;

FIG. 10 is a schematic perspective view of another device of the present invention;

FIGS. 11(a) and 11(b) illustrate steps in the manufacture of the device of FIG. 9;

FIGS. 12(a) and 12(b) are schematic views illustrating different encapsulation techniques;

FIGS. 13(a) and 13(b) are a side view and a plan view illustrating another embodiment of the invention; and

FIGS. 14(a) and 14(b) are a side view and a plan view illustrating another embodiment of the invention.

### BEST MODE FOR CARRYING OUT THE INVENTION

The invention will be described with reference to examples in which the low dimensional structures are elongate structures. However, the invention is not limited to this particular form of low dimensional structures.

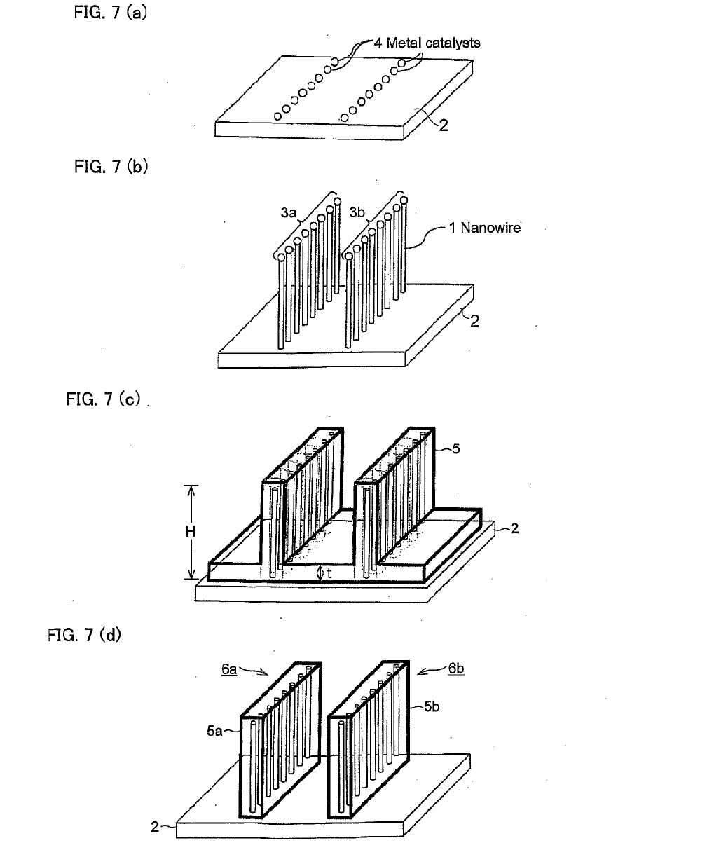

FIGS. 7(a) to 7(e) show principal steps of a method according to one embodiment of the present invention.

Initially a plurality of low dimensional structures, in this example elongate structures 1, are formed over a formation substrate 2. The low dimensional structures may be formed on the formation substrate 2 by an additive process, or they may be formed by subtractive methods, such as lithography and etching. In this embodiment the low dimensional structures 1 are nanowires, but the invention is not limited to this. According to the invention, the elongate structures that are formed over the formation substrate 2 are arranged in groups. The description of this embodiment will refer to just two groups 3a, 3b for simplicity, but the invention is not limited to just two groups.

The spacing between one group and a neighbouring group is greater than the maximum spacing between adjacent nanowires in a group. In principle, the spacing between a group and a neighbouring group may be any spacing that ensures that adjacent groups do not merge following the process of formation of a matrix (to be described below).

In one formation method suitable for use in the invention, a suitable catalyst 4 is initially disposed on the surface of the formation substrate 2 at every location where it is desired to form a nanowire, as shown in FIG. 7(a). The catalyst 4 may be, for example, a metal catalyst. The catalyst 4 may be deposited by, for example a combination of sub-micron lithography/imprinting and lift-off, or by the deposition of a metal colloidal material.

Next, as shown in FIG. 7(b), nanowires 2 are formed at each location where the catalyst 4 was deposited on the surface of the formation substrate 2. Formation of nanowires does not occur at locations where the catalyst 4 is not present. Thus, if the locations where the catalyst 4 is deposited on the surface of the formation substrate 2 are arranged in groups, the result is that the nanowires 1 formed on the formation substrate 2 are also arranged in groups 3a, 3b.

The low dimensional structures 1 formed on the formation substrate preferably have a substantially unidirectional orientation. In FIG. 7(b) the nanowires are shown as oriented with their longitudinal axes generally perpendicular to the formation substrate 2—as explained above, this may provide better control of the formation process.

The nanowires 1, or other low dimensional structures, may be formed by any suitable method. The nanowires may be formed by any suitable technique, for example by epitaxial vapour-liquid-solid or catalyst-free chemical vapour deposition or molecular beam epitaxy, or they may be formed by deposition of material in a porous sacrificial template. A subtractive formation process such as sub-micron lithography and etching may also be used. For example, silicon nanowires may be formed using an Au catalyst in a (111) surface of a silicon formation substrate. The nanowire material can be any suitable material such as, for example, semiconductors, silicides, metal oxides, nitrides and any combination of the aforesaid materials forming any heterostructure. Furthermore the nanowire material may include undoped materials or doped materials with any doping profile. Typically the nanowires will have a diameter of less than 200 nm and a length of 0.1-100 μm. The pitch of nanowires in a group will typically be less than 1 μm.

Next, the groups 3a, 3b of nanowires are encapsulated in a matrix 5. This may be effected by the conformal deposition of one or more layers of encapsulant material over all the exposed surfaces of the nanowires 1 and the formation substrate 2 to form the matrix 5, for example using a substantially isotropic deposition method such as chemical vapour deposition. The matrix must be formed to a thickness sufficient to fill the spaces between adjacent nanowires 1 in a group. As shown in FIG. 7(c), the result of the encapsulation step is that the first group of elongate structures and the second group of elongate structures are each encapsulated in the matrix. Since the required thickness of the matrix is, as explained below, slightly greater than the maximum spacing between adjacent nanowires in a group, and since the spacing between adjacent nanowires in a group is typically less than the length of the nanowires, the thickness t of matrix formed over a region of the substrate where nanowires were not formed is typically much less than the thickness H of matrix formed over a region of the substrate where nanowires were formed. Thus, the matrix encapsulating the first group 3a of nanowires is continuous with the matrix encapsulating the second group 3b of nanowires only near the formation substrate 2.

The material(s) used for the matrix in this embodiment is/are constrained to those which are compatible with the particular formation method. In a case where a chemical vapour deposition process is used, suitable materials include silica and degeneratively doped polysilicon.

Next, the matrix is removed from regions of the formation substrate where nanowires were not formed. The result of this step is shown in FIG. 7(d). The matrix may be removed by any suitable method, for example by an anisotropic etch of the exposed horizontal surfaces of the matrix.

As can be seen in FIG. 7(d), the effect of removing the matrix from regions of the formation substrate where nanowires were not formed is to separate the matrix 5a encapsulating the first group 3a of nanowires from the matrix 5b encapsulating the second group of nanowires. The result is a “fin-type structure” 6a, 6b that contains a group of nanowires 1 encapsulated in a matrix 5a, 5b.

Each fin-type structure 6a, 6b may be removed from the formation substrate 2 and transferred to a target substrate 7, as shown in FIG. 7(e). Since the contact area between each fin-type structure 6a, 6b and the formation substrate 2 is relatively low, it is much easier to remove a fin-type structure 6a, 6b from the formation substrate 2 than it is to remove the composite structure of U.S. Pat. No. 7,091,120 from its formation substrate.

In this embodiment the function of the matrix 5, 5a, 5b is to support/lock the nanowires 1 in a fixed position relative to one another, so that the position, orientation and alignment of nanowires in a fin-type structure 6a, 6b, relative to other nanowires in that fin-type structure, are preserved during the removal of the fin-type structure from the formation substrate and its transfer to the target substrate 7, and also to provide a handle by which the nanowires can be simultaneously detached from the formation substrate 1 and transferred to the target substrate.

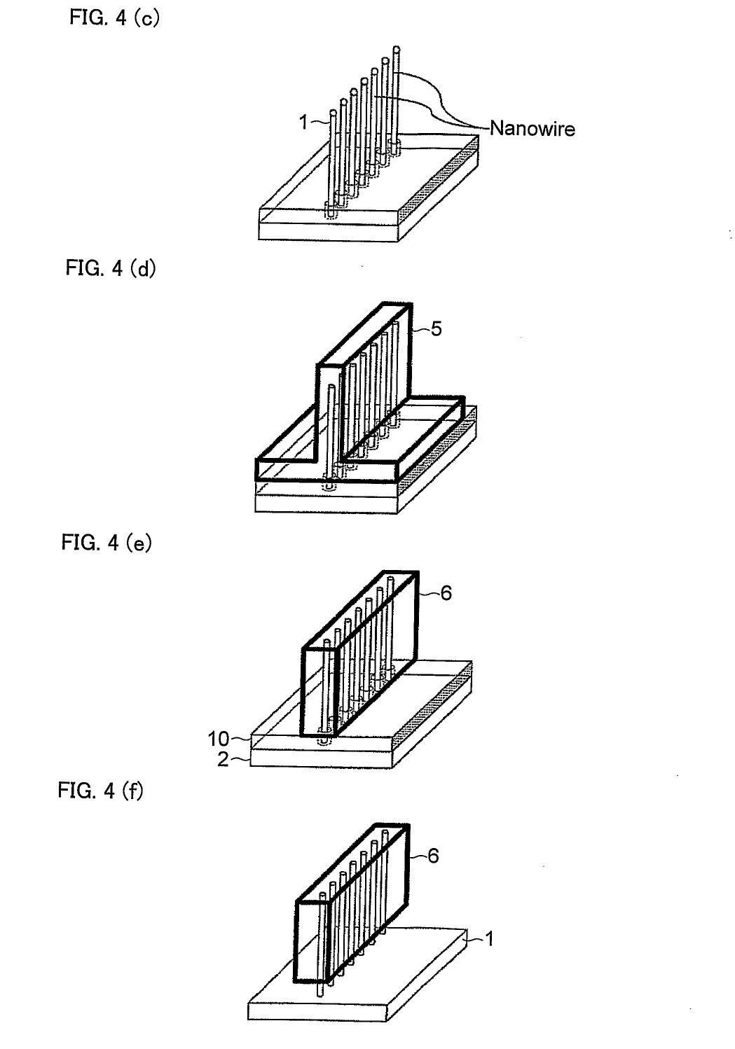

The term “fin-type” structure is used herein to denote a structure with a high aspect ratio, in which the shortest dimension of the encapsulant (denoted as W in FIG. 3, with W<H and W<D) extends parallel to a surface plane to which the structure is attached.

The fin-type structure may be transferred to the target substrate such that the orientation of the nanowires relative to the target substrate 7 is different from the orientation of the nanowires relative to the formation substrate 1. For example, as shown in FIG. 7(e), the fin-type structure may be deposited on the target substrate such that the longitudinal axes of the nanowires extend generally parallel to the target substrate. The fin-type structure thus becomes a “tape-type structure” on the target substrate. The term “tape-type” structure is used herein to denote a structure with a high aspect ratio, in which the shortest dimension W of the encapsulant (shown in FIG. 3) extends perpendicular to a surface plane to which the structure is attached.

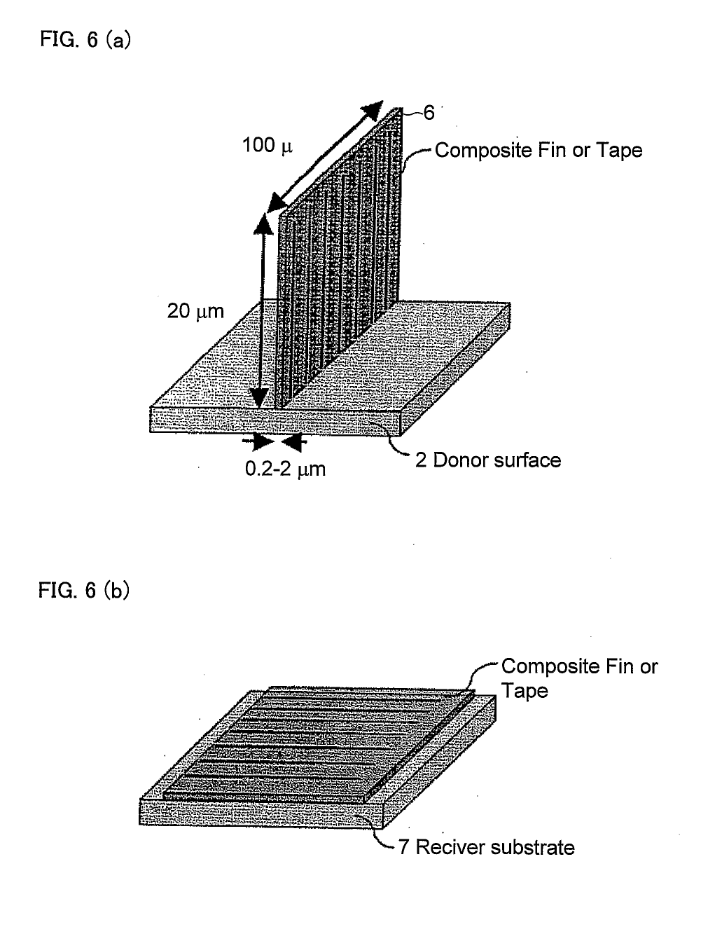

Transfer of a fin-type structure 6 from a formation substrate, and its deposition on a target substrate as a tape-type structure is also shown in FIGS. 6(a) and 6(b).

Once the fin-type structure 6a, 6b has been transferred to the target substrate, the matrix 5a, 5b can optionally be partially or completely removed to leave an array of partially or completely exposed nanowires that can be subsequently processed into devices.

Alternatively, as is described in more detail below, the matrix may perform an active function or a passive function in a finished device.

A fin-type structure may consist of at least two, and typically several hundred nanowires, and may consequently have typical dimensions of a height above the substrate of 20 μm, a thickness of 0.2-2 μm, and a length of 100 μm or greater. The number of nanowires in a fin-type structure is defined by the arrangement of nanowires in the group, which is defined in the formation process. In an embodiment in which the nanowires in a group are arranged along a line, the number of nanowires in a fin-type structure is given by the length of the fin-type structure divided by the spacing between adjacent nanowires.

A tape-type structure obtained by a method of the present invention may optionally be patterned into multiple smaller segments after it has been transferred to the target substrate, using one or more selective and subtractive lithographic techniques whereby at least a portion of the matrix lying between two nanowires is removed.

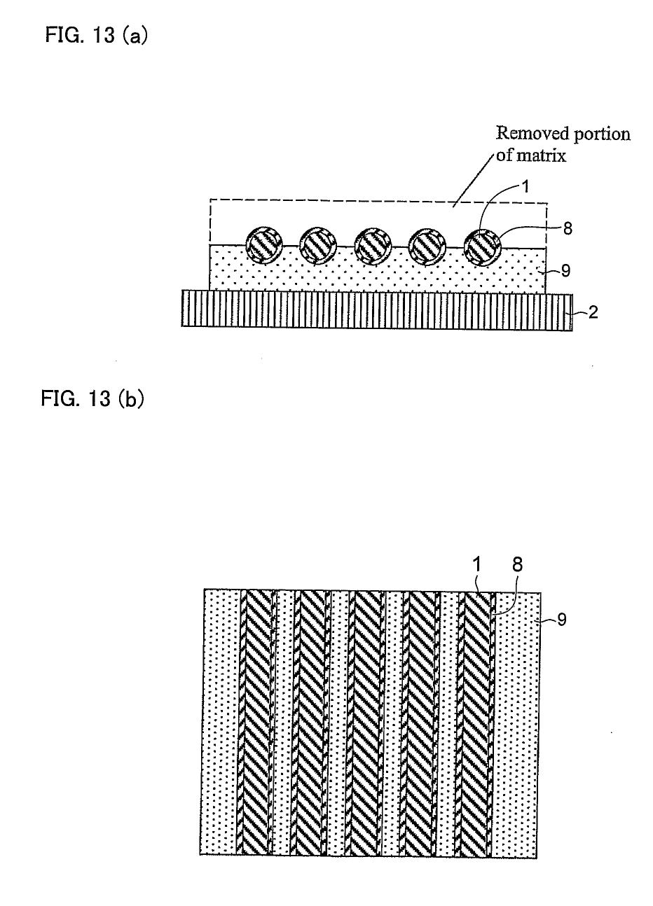

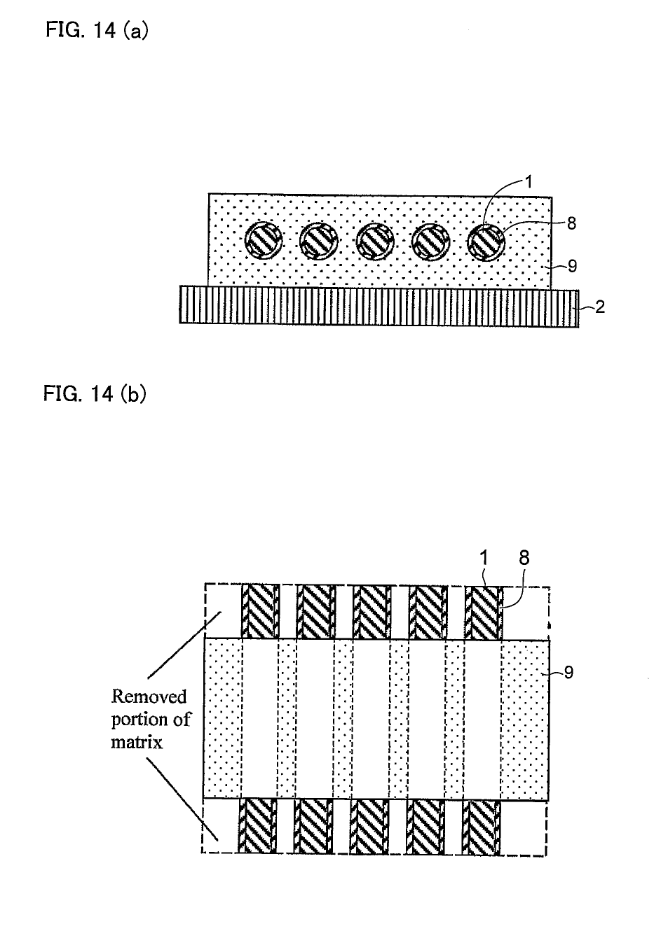

Additionally or alternatively, a tape-type structure obtained by a method of the present invention may optionally be processed by removing a portion of the matrix such that at least a portion of one or more of the nanowires is not covered by the matrix but is exposed. This is illustrated in FIGS. 13(a) to 14(b).

FIGS. 13(a) and 13(b) are respectively a side view and a plan view of a tape-type structure obtained by a method of the present invention after it has been further processed to remove the matrix overlying the nanowires 1 so as to expose the nanowires. The portion of the matrix that has been removed is indicated by broken lines in FIG. 13(a).

In FIGS. 13(a) and 13(b) the overlying matrix has been removed so as to expose the nanowires 1 along their length. The nanowires remain embedded in the matrix, but their upper surfaces are exposed.

This embodiment is not however limited to this, and the matrix may be removed such as to expose only parts of the nanowires. FIGS. 14(a) and 14(b) are respectively a side view and a plan view of a tape-type structure obtained by a method of the present invention after it has been further processed to remove only the matrix overlying parts of the nanowires 1—in the example shown the matrix overlying the ends of the nanowires 1 has been removed so as to expose the ends of the nanowires. The matrix overlying the central portions of the nanowires has not been removed, however, and the central portions of the nanowires remains covered by the matrix.

The present invention provides a number of advantages over the prior art. The geometry and structure of the fin-type structure means that it can be both easily detached from the first substrate 2 on which it is formed and applied to a second substrate 7 such that the longitudinal axes of the elongated structures are parallel to the plane of the second substrate, as illustrated in FIGS. 6(a) and 6(b).

The absolute dimensions and aspect ratio of the fin-type structure are constrained by the dimensions, number and spacing of the nanowires; in contrast, in U.S. Pat. No. 7,091,120 these are determined by the limitations of the particular lithographic and etch processes use to pattern the matrix material. The number of elongated structures contained in each piece of tape is determined by the number of elongated structures in the initial line, not by subsequent lithography. As a result, the invention provides much better control over the number of nanowires in a fin-type structure, over the position of nanowires in a fin type-structure, and over the aspect ratio of the fin-type structure.

The matrix can be deposited from the vapour phase (whereas the method of U.S. Pat. No. 7,091,120 requires deposition of a liquid matrix material). Vapour phase deposition enables the possibility of utilising many more materials to form the matrix and, in particular, makes it possible for important classes of materials such as elemental and compound semiconductors, as well as important dielectric materials such as silica and silicon nitride, to be used as or in the matrix.

The arrangement of elongated structures contained in each block relative to the external dimensions of the block is determined by the thickness of the matrix layer deposited, not by subsequent patterning/lithography.

In the method of FIGS. 7(a) to 7(e), it may be desirable to facilitate the transfer of the fins to the target substrate by first ‘knocking over’ the fins 6a, 6b on the formation substrate so that they are lying flat before they are transferred to the target substrate. This effectively imposes the constraint on the minimum spacing of the fins to be greater than the height of the fins.

This is illustrated in FIGS. 7(f)(i) and 7(f)(ii). FIG. 7(f)(i) shows two sets of fins, one set of two fins 6a, 6b with a separation Si and height H, where S₁>H, and a second set of five fins 6a′, 6b′, 6c′, 6d′, 6e′ with separation S₂<H. FIG. 7(f)(ii) shows the same sets of fins after they have been “knocked over” on the formation substrate ready for transfer. If the separation of the fins is not sufficient then there will be some overlap of the ‘knocked over’ fins, as shown for the set of five fins 6a′, 6b′, 6c′, 6d′, 6e′.

Overlap of the ‘knocked over’ fins can be undesirable, as it may impede transfer of the fins to the target substrate.

The separation between adjacent fins is, ignoring the thickness of the matrix, equal to the spacing between adjacent groups 3a, 3b of elongate structures in FIG. 7(b), and the height of the fins is approximately equal to the height of the original elongate structures. If it is desired that the ‘knocked over’ fins do not overlap, the spacing between adjacent groups must be at least equal to the height of the elongate structures. For elongate structures having the typical height of 20 μm mentioned above, this requires that the spacing between adjacent groups is 20 μm or greater.

Conversely, in some cases it may be desired that there is some overlap of the ‘knocked over’ fins, as shown for the set of five fins 6a′, 6b′, 6c′, 6d′, 6e′ in FIG. 7(f)(ii), for example to increase the optical path length of the resultant structure for applications involving absorption of light (for example, solar cells or optical detectors). In such a case, the spacing between adjacent fins must be less, preferably considerably less, than the height of the fins. In turn, this requires that the spacing between adjacent groups 3a, 3b of elongate structures is less, preferably considerably less, than the height of the elongate structures (while still being large enough such that adjacent groups of elongate structures do not merge following formation of the matrix).

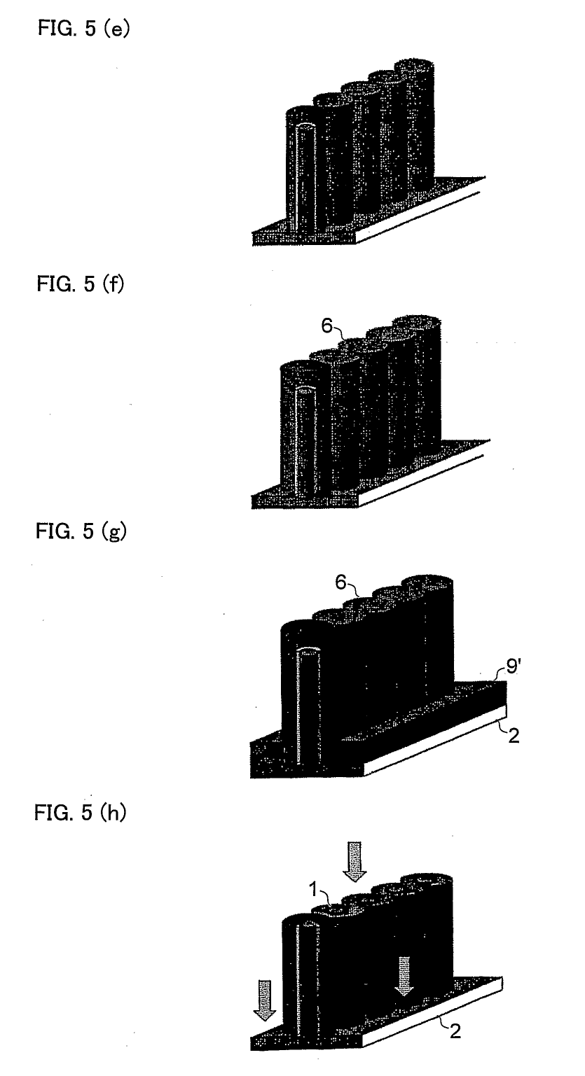

FIGS. 5(a) to 5(g) show one method of encapsulating the nanowires 1 in more detail. (Only one group of nanowires is shown in FIGS. 5(a) to 5(g), for simplicity.)

FIG. 5(a) shows the nanowires 1 after they have been formed on the formation substrate 2, and corresponds generally to FIG. 7(b).

FIG. 5(b) illustrates formation of a layer of a first encapsulant material 8 over the nanowires 1. As explained above, the first encapsulant material is preferably formed using a substantially isotropic formation method such as chemical vapour deposition, so that the first encapsulant material is formed on the exterior surfaces of all the nanowires as a first conformal layer. The first encapsulant material is also formed on the exposed parts of the surface of the formation substrate 2, although this material is omitted from FIGS. 5(b) to 5(f) to avoid obscuring the figures.

Next, a layer of a second encapsulant material 9 different from the first encapsulant material 8 is formed, as shown in FIG. 5(c). The second encapsulant material is preferably formed using a substantially isotropic formation method such as chemical vapour deposition, so that the second encapsulant material is formed on the entire area of the first encapsulant material formed on the nanowires, as a second conformal layer. (The second encapsulant material is also formed on the first encapsulant material formed on the exposed parts of the surface of the formation substrate 2, although this material is omitted from FIGS. 5(c) to 5(f) to avoid obscuring the figures.)

In this embodiment, formation of the second encapsulant material 9 is continued, as shown in FIGS. 5(d) and 5(e), until the second encapsulant material formed around one nanowire merges with the second encapsulant material formed around an adjacent nanowire to form a matrix that encloses all nanowires of a group, thereby producing a fin-type structure 6 as shown in FIG. 5(f). At this point, the matrix encapsulates the complete group of nanowires.

In the embodiment of FIGS. 5(a) to 5(f), the first encapsulant material 8 and second encapsulant material 9 are different materials and so will have different properties, for example such as different electrical or optical properties. For example the first and second encapsulant materials may each consist of silicon but have different doping levels and/or doping types so as to have different electrical properties from one another. Alternatively, the first encapsulant material 8 may, for example, be an electrically insulating material that electrically insulates the nanowires 1 from the second encapsulant material 9.

In an embodiment in which the first encapsulant material 8 is an electrically insulating material, the step of forming the first encapsulant material 8 may be a thermal oxidation step in which the exposed surfaces of the nanowires are oxidised at a temperature of around 1000° C.

The method of FIGS. 5(a) to 5(f) does not require that exactly two layers of different encapsulant materials are formed. The method may be effected by forming more than two layers of different encapsulant materials. Conversely, the method may be effected by forming only a single encapsulant material—in this case, formation of the first encapsulant material would continue until the first encapsulant material formed around one nanowire merges with the first encapsulant material formed around an adjacent nanowire to form a matrix of a fin-type structure 6.

The matrix formed over the top surfaces of the nanowires may also be removed, for example using an etching process, to expose the upper ends of the nanowires. This is shown in FIGS. 5(g) and 5(h). FIG. 5(g) corresponds generally to FIG. 5(f) and shows the elongate structures after encapsulation to form a fin-type structure 6, except that FIG. 5(g) also shows encapsulant material 9′ formed on the exposed surface of the formation substrate.

FIG. 5(h) shows the fin-structure after an anisotropic etch-back of horizontal surfaces (as shown schematically by the arrows in FIG. 5(h)) to remove the encapsulant material formed over the top surfaces of the elongate structures, to expose the upper ends of the elongate structures. As indicated in FIG. 5(h), this etching step is also effective to remove any encapsulant material 9′ formed on the exposed surface of the formation substrate.

It will be appreciated that, where encapsulant material is formed over the exposed surfaces of the formation substrate, as shown in FIG. 5(g), a fin-type structure will be connected to an adjacent fin-type structure by the encapsulant material formed over the exposed surfaces of the formation substrate. Removal of the encapsulant material formed over the exposed surfaces of the formation substrate is required to separate one fin-type structure from an adjacent fin-type structure, and this may be effected in any suitable way. Where an etching process is used to remove the encapsulant material formed over the exposed surfaces of the formation substrate in order to separate the fin-type structures from one another, the etching process would normally also remove the encapsulant material formed over the top surfaces of the elongate structures and thereby expose the upper ends of the elongate structures. If it is not desired to expose the upper ends of the elongate structures, the top surfaces of the fin-type structures must be masked during the etching step.

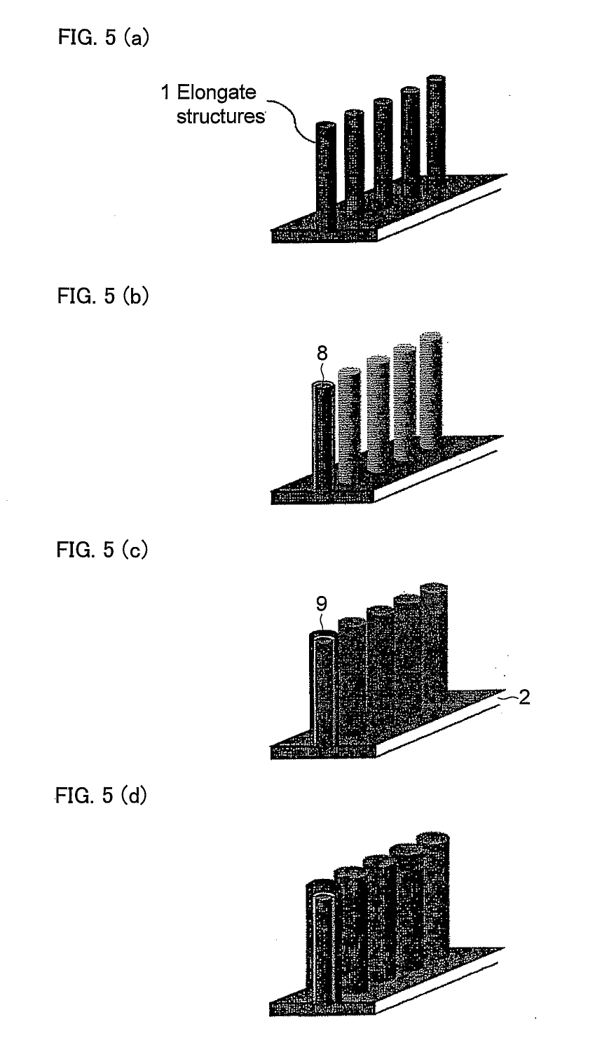

In principle it is possible to form the encapsulant material(s) selectively between/around the elongate structures without simultaneously forming the encapsulant material(s) on the exposed portions of the substrate. In such a case, the matrix encapsulating a group of elongate structures is not continuous with the matrix encapsulating an adjacent group of elongate structures, and the encapsulant material 9′ of FIG. 5(g) is not present. This is possible, for example, by using selective epitaxial growth (SEG) of silicon. During epitaxial CVD of silicon layers, growth of silicon on silica surfaces can be avoided by the introduction of HCl (hydrogen chloride) gas into the process gas mixture. Thus, if silicon elongate structures are formed through holes in a silica layer disposed over a silicon substrate (in the manner described with reference to FIGS. 4(a) to 4(f) below), it is possible to selectively and isotropically form a matrix of silicon around the elongate structures but not on the exposed portions of the substrate between groups of elongate structures.

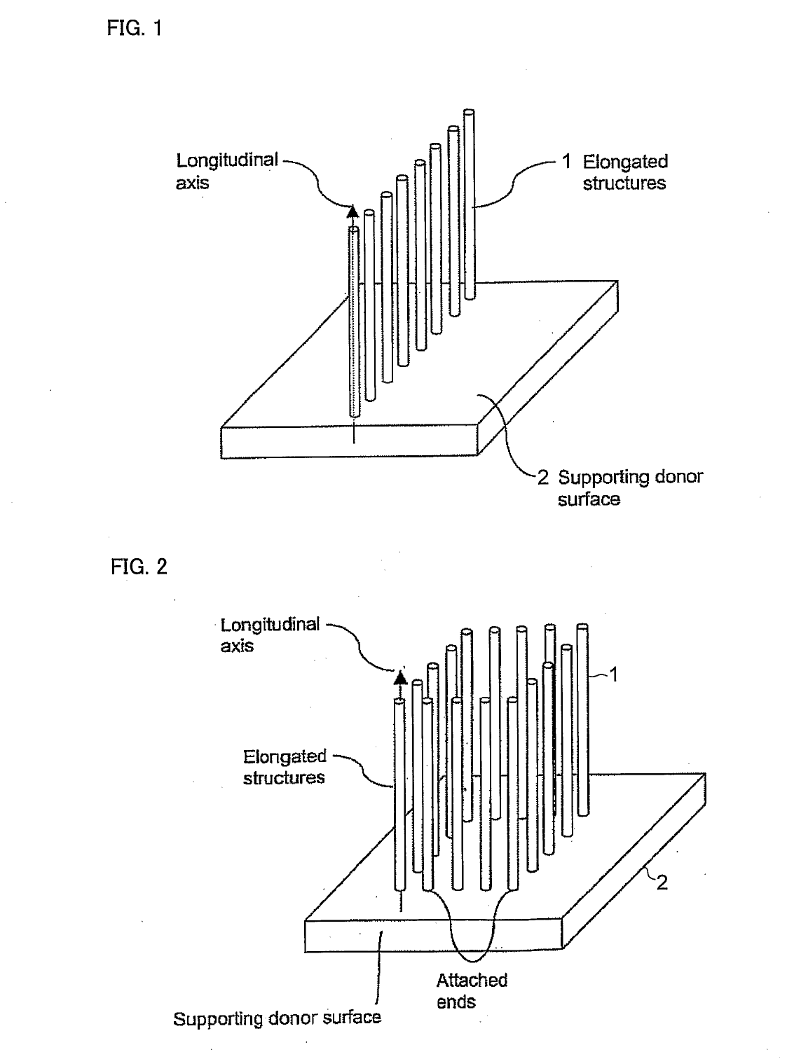

FIG. 3 is a schematic illustration of a fin-type structure 6 encapsulating a group of nanowires 1, where the nanowires are arranged along a straight line. The group of nanowires before encapsulation is shown in FIG. 1. The side surfaces of the fin structure 6 of FIG. 3 have been made planar, as described below, and are parallel to one another.

The fin-type structure 6 has a height H measured perpendicular to the formation substrate, a width W and a length D. If the group contains N nanowires, and the nanowires are regularly spaced with a separation d between each pair of adjacent nanowires, then the length of the fin-type structure is given by D≈N×d. That is, the length D of the fin-type structure is constrained by the total number N and average spacing d of nanowires in the line group.

The width of the fin-type structure is constrained by the maximum spacing dₘₐₓ between any two adjacent nanowires in the line group. In order for the matrix surrounding one nanowire to merge with the matrix surrounding an adjacent nanowire in the same group that is spaced a distance dₘₐₓ away, it is necessary that the matrix is formed on each nanowire to a thickness ½ dₘₐₓ, so that the minimum width of the fin-type structure will be dₘₐₓ. (Of course, the matrix may be formed to a thickness of greater than ½ dₘₐₓ, in which case the width of the fin-type structure will be correspondingly greater.)

If desired, the curved side surfaces of the fin-type structure 6 may be made planar, to give a fin-type structure with substantially flat side surfaces as shown in FIG. 3. Planarisation may be achieved either through selective removal of material (e.g. etching or chemical mechanical polishing), addition of new material (e.g. deposition), or a combination of the two. Clearly, if there is a net removal of material in a planarisation process then the limitation that the minimum thickness of the fin-type structure, after planarisation, is dₘₐₓ will not necessarily hold. The thickness before planarisation must, however, be dₘₐₓ or above—ie, the minimum thickness of the fin-type structure as initially formed on the formation substrate must be greater than dₘₐₓ.

In this connection, it should be noted that it would be difficult (but not impossible) to planarise the sidewalls of the fin while the fin is vertically oriented on the formation substrate. If planarisation is required it is more likely that one or both sides of the fin-structure would be planarised when the fin is lying flat (is, as a tape-type structure), either during the transfer process (for example, while on an intermediate substrate such as a stamp) or when the tape is on the receiver substrate.

The aspect ratio of the fin-type structure is defined as H/W. The aspect ratio may be made as large as desired, by suitably forming the groups of nanowires. The aspect ratio of a fin-type structure produced by the method the invention may be 10:1 or greater, 20:1 or greater, 100:1 or greater, or even 200:1 or greater.

The height H of the fin-type structure is constrained by the length of the nanowires and, in the embodiment of FIGS. 7(a) to 7(e) is substantially equal to the length of the nanowires.

In the method of the invention, the spacing between one group and an adjacent group is made much greater than the maximum spacing between any two adjacent nanowires in any group. This ensures that the fin-type structure produced around one group of nanowires will not merge with the fin-type structure produced around an adjacent group of nanowires. Formation of one or more layers of encapsulant material possessing an overall thickness equal to or greater than half the separation distance between nanowires within one group results in a merging of the encapsulant material formed around one nanowire with the encapsulant material formed around an adjacent nanowire of the group to form a matrix—however, the thickness of the formed encapsulant material is insufficient to cause encapsulant material formed around one nanowire to merge with encapsulant material formed around a nanowire of another group. Thus a plurality of fin-type structures is formed, one for each group of nanowires.

FIGS. 4(a) to 4(f) show the principal steps of another method of the present invention. This method will again be described with reference to an embodiment in which the low dimensional structures are nanowires. These figures shown only one group of nanowires, but this method may be applied in a case where nanowires are formed in a plurality of groups.

Initially, one or more layers are formed over the surface of a formation substrate 2 as shown in FIG. 4(a). Only one layer 10 is shown in FIG. 4(a) but the invention is not limited to this. The layer(s) 10 may be formed by any suitable process and may be any material(s) that can be processed selectively from the encapsulant material(s) to be formed in a later step of the method. The layer(s) 10 may comprise, for example, a silica layer or a silicon nitride layer which are suitable material when using silicon as the encapsulant material to form the matrix. The or each layer 10 may be regarded as a “sacrificial layer”, for reasons that are explained below.

Next, an aperture 11 is formed in the sacrificial layer 10 at each location where it is desired to form a nanowire, as shown in FIG. 4(b). Each aperture extends through the sacrificial layer 10, so as to expose the formation substrate 2. The apertures may be formed by any suitable process, for example a masking and etching process, a combination of lithography and wet or dry etching, electron-beam lithography, imprint lithography, optical lithography or interference lithography and reactive ion etching.

If desired, a catalyst, for example a metal catalyst, for formation of the nanowires may be deposited in each aperture 11. If this is done, the step of forming the apertures may be combined with a suitable lift-off technique in order to deposit the catalyst in the apertures before the nanowire formation step.

Next, nanowires 1 are formed and are encapsulated in a matrix 5 to form a fin-type structure 6, as shown in FIGS. 4(c) and 4(d). FIG. 4(c) illustrates the structure after growth of nanowires 1, and FIG. 4(d) illustrates the structure after the conformal deposition of a matrix 5 over all surfaces. These steps correspond generally to FIGS. 7(b) and 7(c), and their description will not be repeated.

The horizontal surfaces of the matrix 5 are then etched back, preferably using an anisotropic etching process, to remove the matrix formed on regions of the formation substrate where no nanowires were formed. The result of this step is shown in FIG. 4(e). (As explained above, this step will also result in removal of the matrix from the upper surface of the fin-type structure, unless the upper surface of the fin-type structure is masked.)

Next, the or each sacrificial layer 10 is removed, as shown in FIG. 4(f). This may be done using any suitable technique that does not affect the fin-type structure 6 such as, for example, such as isotropic dry or wet chemical etching, possibly in combination with an anisotropic dry or wet chemical etching step. For example, if the matrix is made of polysilicon then a silicon nitride or silica layer can be selectively wet chemically etched using hydrogen fluoride (HF) solution.

In this embodiment the fin-type structure 6 has a very small footprint on the formation substrate 2, as the fin-type structure 6 is attached to the formation substrate 2 only by the nanowires 1. The matrix 5 does not make contact with the formation substrate 2. It is therefore very easy to detach the fin-type structure 6 from the formation substrate 2 for transfer to a target substrate.

The method of FIGS. 4(a) to 4(f) may be applied in a method in which the nanowires are arranged in groups on the formation substrate 2, for example as described with reference to FIGS. 7(a) to 7(f). However, the method of FIGS. 4(a) to 4(f) does not require that the nanowires are arranged in groups on the formation substrate 2, and may be applied for any arrangement of nanowires on the formation substrate 2.

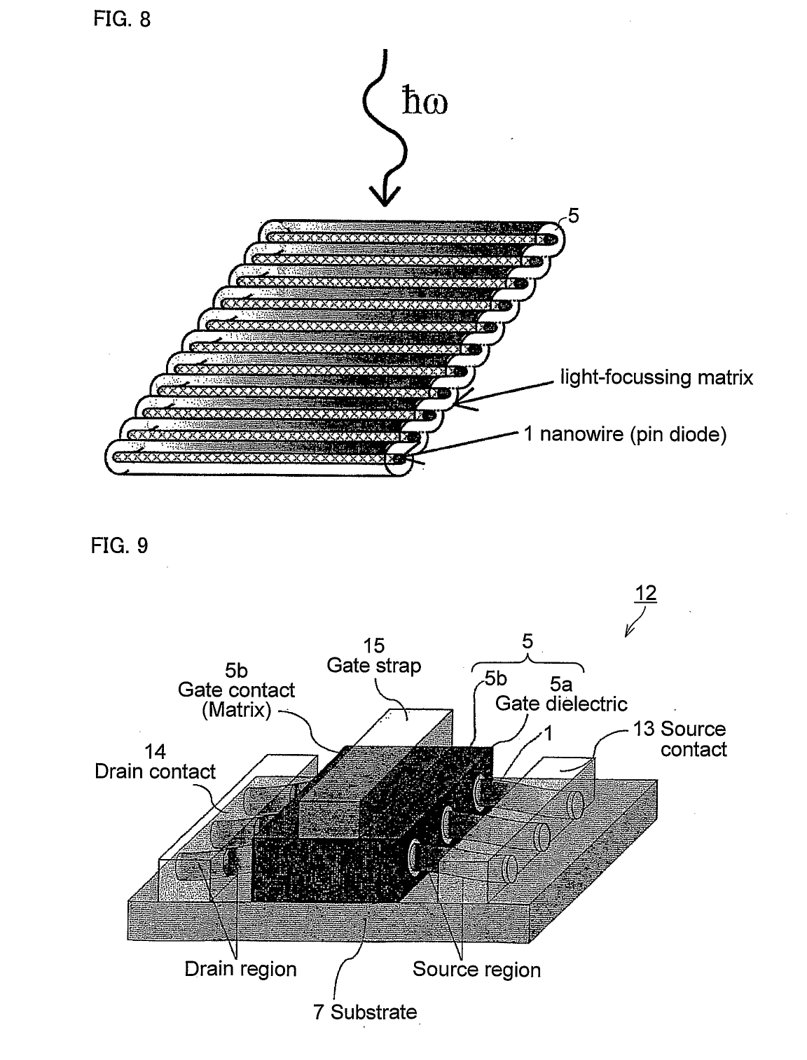

The matrix 5 formed by a method of the invention may be an inert matrix that functions only to provide support for the nanowires during removal of the fin-type structure from the donor substrate and its transfer to a target substrate. In such a case the matrix may be formed of any material(s) that provides adequate support and other properties of the matrix are not important—the matrix may for example be transparent or opaque, electrically conductive or non-conductive, etc. Alternatively, the matrix may perform an active or passive function in a device in which the fin-type structure or tape-structure is incorporated, and in such a case the matrix is required to be formed of material(s) having appropriate properties for this function. FIG. 9 illustrates an embodiment of the invention in which the matrix performs a function in a resultant device.

In the embodiment of FIG. 9, the matrix comprises two sequentially formed layers 5a, 5b around an array of semiconducting nanowires 1. The first layer 5a is layer of a dielectric material such as silica and can be formed either by chemical vapour deposition (CVD), physical vapour deposition or thermal oxidation. The second layer is a conducting layer such as, for example, highly doped polysilicon which can be deposited by CVD and then thermally annealed to cause it to recrystallise. In this embodiment the layers 5a, 5b act as both a support for the nanowires and as part of a subsequent thin film transistor device structure. For example the matrix can be used to form a gate stack in a transistor, in which the nanowires 1 provide the source, drain and channel regions. The first layer 5a forms the gate dielectric, and the second layer 5b forms the gate electrode. In this embodiment the first layer 5a of encapsulant material is localised around each individual nanowire and does not merge with the corresponding layer localised around an adjacent nanowire to form a single structure. As such, the first layer 5a could be considered as part of the nanowire.

The transistor 12 of FIG. 9 comprises a group of nanowires that have been encapsulated in a matrix containing two layers of different encapsulant material, for example according to a method of FIG. 4(a) to 4(f) or 7(a) to 7(f) with two different materials being formed as described with reference to FIGS. 5(a) to 5(e). The encapsulated group of nanowires is transferred to a target substrate, and is disposed on the target substrate so as to form a tape-like structure.

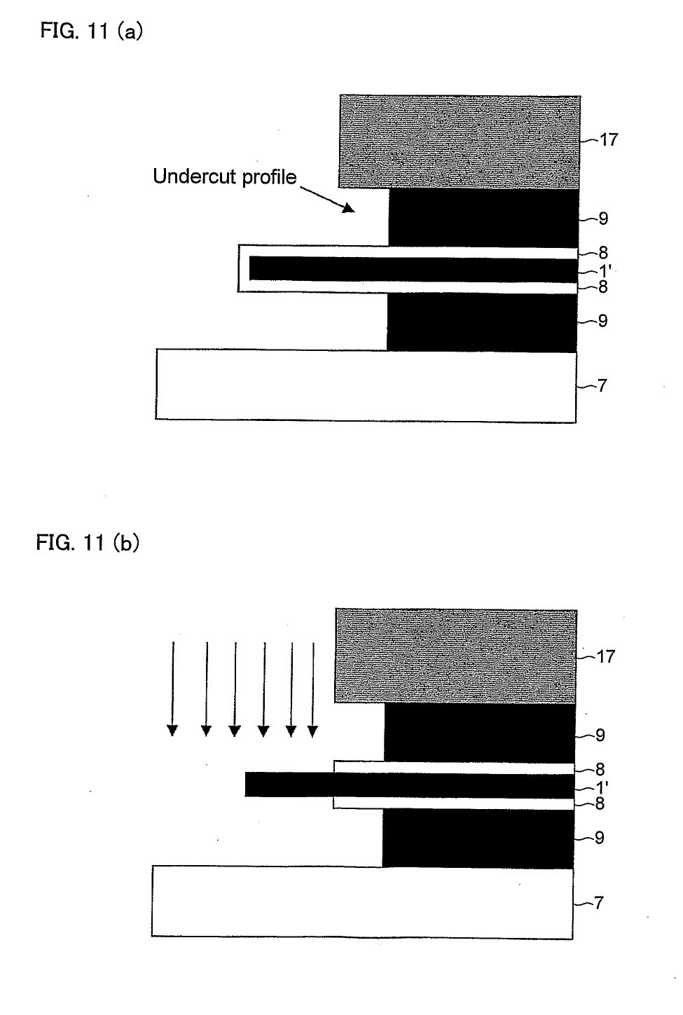

The matrix is then etched to expose the upper and lower ends of the nanowires 1. A suitable method for this is illustrated in FIGS. 11(a) and 11(b).

Initially, a masking material 17 (e.g. SiO2 or a metallic layer) is deposited over the tape-type structure after it has been deposited on the receiver substrate 7. The masking material 17 may or may not be sacrificial. Subsequently photoresist (not shown in FIG. 11(a)) is deposited over the masking material 16 and is patterned using photolithography to expose the areas of the masking material where contacts to the encapsulated nanowires are to be made.

The exposed areas of the masking material 17 are then removed to expose the encapsulated nanowires, for example using etching with hydrofluoric acid (HF) or reactive ion etching (RIE) in a case where silica (SiO2) is used as the masking material.

Next, an isotropic, dry or wet-chemical etch, such as potassium hydroxide (KOH) solution in the case of polysilicon matrix, is applied to the exposed matrix. This will etch the outer layer 9 of the matrix all the way around the ends of the nanowires. The thermal oxide 8 surrounding the nanowire cores 1′ acts as an etch stop layer, preventing the silicon nanowires cores themselves from being etched. Also, the isotropic nature of the etch process will result in an “undercut profile” as shown in FIG. 11(a).

The additional masking material 17 is required because the KOH used in this step strips photoresist.

Next, the exposed thermal oxide 8 is etched using a selective dry etch, to leave the silicon nanowire cores 1′ exposed in the region where the masking material 17 has been removed. The silicon nanowire cores 1′ will not be etched by this process. The result of this etching step is shown in FIG. 11(b).

A suitable electrically-conductive material is deposited over the exposed ends of nanowires 1 to form a source contact 13 and a drain contact 14. A suitable electrically-conductive material is also deposited on the matrix 5 to form the gatestrap 15. Suitable materials for the electrically-conductive contacts are any materials commonly used for forming electrical contacts on semiconductor materials such as, for example, Ti, Ni, Cr, Au, Al, Ta, Mo, W, Cu, Pt, or any combination of these materials as multiple layers (for example, to improve adhesion or contact resistance). Depending on the particular contact it may be necessary to dope the nanowire or matrix (for example, by implantation) with a higher concentration of dopants at least beneath where the metal contact will be made.

As noted above, the matrix 5 may be formed more than two layers of material. In a further embodiment of the invention, the matrix consists of four different layers, in sequence:

1. A tunnel insulating layer—for example this embodiment may use silicon nanowires, and the tunnel insulating layer may be composed of silicon dioxide and formed by thermal oxidation of the silicon nanowires;

2. A floating gate composed of, for example, highly doped polysilicon deposited by CVD;

3. A control insulating layer composed of, for example, thermally grown or CVD deposited silicon dioxide; and

4. A control gate composed of, for example, highly doped polysilicon deposited by CVD.

The thickness of the tunnel insulating layer and the floating gate are such that they are localised to the individual nanowires (i.e. the tunnel insulating layer and the floating gate disposed around one nanowire do not merge with the tunnel insulating layer and the floating gate disposed around an adjacent nanowire). The thicknesses of the control insulating layer and the control gate are such that either the control insulating layer or the control gate disposed around one nanowire merges with the control insulating layer or the control gate, respectively, disposed around an adjacent nanowire.

The encapsulated group of nanowires is transferred to a target substrate, and is disposed on the target substrate so as to form a tape-like structure. After transfer to the target substrate the tape-like structure can be processed into a floating gate memory array where each nanowire can be used to store a single bit of data.

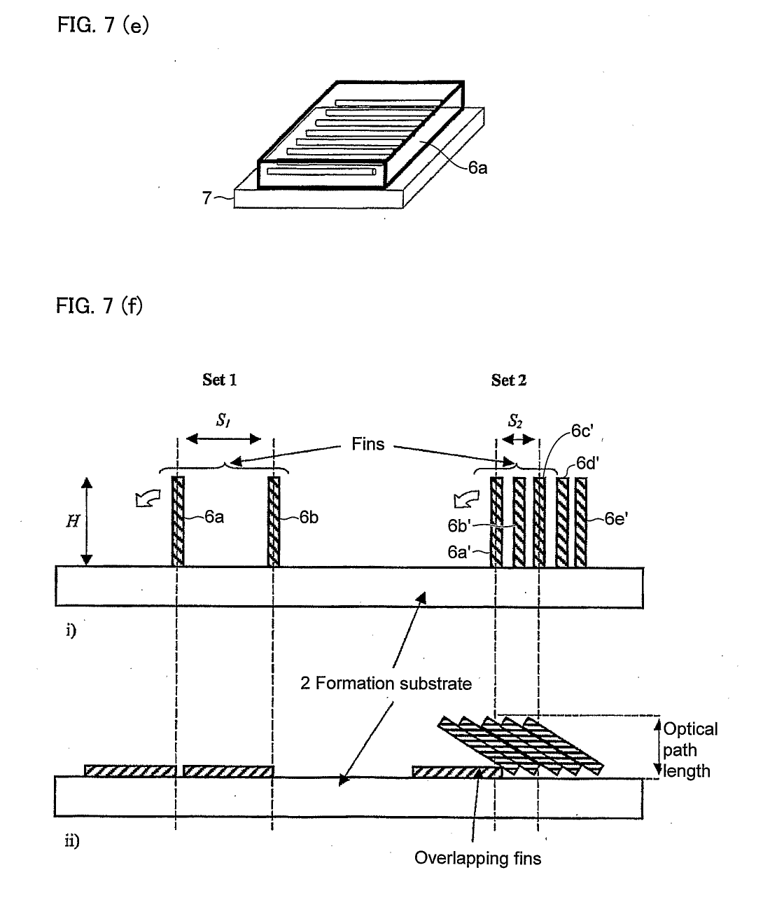

In a further embodiment the matrix 5 may function as a light focusing/redirecting layer, and combine with the function of the nanowires (e.g. which act as pin diodes) to form a sensitive optical detector or photovoltaic device. This embodiment is illustrated in FIG. 8. In this embodiment, the matrix 5 is formed of a light-transmissive material, and is shaped such that the side face consist of a plurality of portions of cylindrical lenses. Light incident on the side faces of the matrix 5 is focused onto the nanowires 1 (which are positioned substantially along the focal line of each cylindrical lens.

Light-emitting nanowires are known. The light emitted from nanowires is polarised with a polarization axis parallel to the longitudinal axis of the nanowire. In a further embodiment of the invention, the matrix 5 functions as a light absorbing layer such that optical energy is absorbed by the matrix and transferred to the nanowire, and spontaneously subsequently re-emitted with a defined polarization and wavelength.

Alternatively, the matrix may be transmissive and the nanowires can be driven electrically to emit light via electrical contacts made either directly to the nanowires or to an electrically conductive material included in the matrix.

As a further alternative, the matrix (or at least one layer thereof in the case of a matrix comprising layers of two or more different material) may be optically emissive.

In general the encapsulant layer, or each encapsulant layer if there are two or more encapsulant layers, may be chosen to have any desired properties. For example, the encapsulant layer, or at least one of the encapsulant layers if there are two or more encapsulant layers, may be transparent or opaque, may be electrically insulating or electrically conductive, may be optically emissive, may be heterogeneous, etc. (By “heterogeneous” is meant that the encapsulant material(s) is not homogeneous, for example, in composition or structure. For example, an encapsulant layer may itself comprise a plurality of ‘guest’ structures (of any size, shape and spatial distribution) made from a first material and encapsulated in a second material. An example of a heterogeneous material would be a silica layer containing a distribution of silicon nanoparticles. Such a composition can be formed by high density plasma CVD process and frequently has luminescent properties. Another example of a heterogeneous material would be a porous material such as, for example, porous anodic alumina.)

In one example, formation of the matrix may comprise forming at least a layer of a first encapsulant material over the low dimensional structures, and transforming at least part of the first encapsulant material to a second encapsulant material different from the first encapsulant material. For example, one encapsulant layer (e.g. silicon) may be formed, and part of this layer may be (thermally) oxidised, for example to convert it to silicon dioxide (silica), so that the resultant matrix contains layers of two different materials. This is sometimes more desirable than depositing two separate layers because a silicon dioxide layer formed (or grown) by thermal oxidation is generally of better quality than a silicon dioxide layer deposited by CVD. This is of use where the matrix is composed of several layers. An example of this would be the floating-gate device embodiment described above. In this particular embodiment the device consists of a tunnel oxide and a floating gate which are localised on each nanowire and do not merge, and a control oxide and control gate which are continuous between adjacent nanowires. Incidentally, this is an example of where (as discussed below) the tunnel oxide and floating gate may be considered as forming part of the nanowire structure and the control oxide and control gate may be considered as forming the matrix.

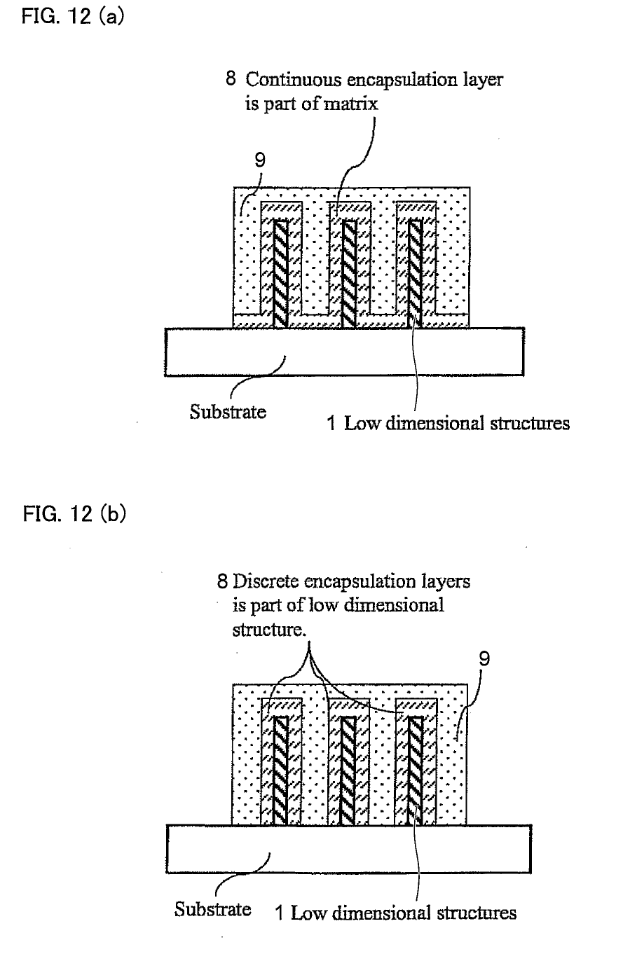

It should be noted that an encapsulant layer that is formed over the low dimensional structures may be considered part of the matrix, or may be considered as part of the low-dimensional structure. For example, if an encapsulant material 8 at a first site of a low-dimensional structure within a group is continuous with the same encapsulant material 8 of a low dimensional structure at a second site within the same group of low dimensional structures (see FIG. 12(a)), the encapsulant material 8 may be considered as part of the matrix. The encapsulant material 8 does not on its own constitute the complete matrix unless its thickness is greater than half the separation between adjacent low-dimensional structures. However, if the sum of the two or more encapsulant layers 8,9 have a total thickness greater the twice the separation of adjacent low-dimensional structures then together they do constitute the matrix.

Alternatively, if an encapsulant material 8 at a first site of a low-dimensional structure within a group is not continuous with the same encapsulant material 8 of a low dimensional structure at a second site within the same group of low dimensional structures (see FIG. 12(b)), the encapsulant material 8 may be considered as part of the low-dimensional structure 1 and not the matrix. Put another way, any material that encapsulates the low-dimensional structures 1 but that is “localised” at each site of each low dimensional structure 1 may be considered part of said low-dimensional structure.

FIGS. 12(a) and 12(b) shows two groups of 3 low-dimensional structures 1 encapsulated by two layers 8,9 of encapsulant material. In the first case (FIG. 12(a)) the matrix is comprised of both layers 8, 9. In the second case (FIG. 12(b)) the matrix comprises a single layer 9 and the other layer 8 of encapsulant material forms part of the substructure of the low-dimensional structures 1.

As an example, thermal oxidation is a process by which a surface layer of silicon reacts with water or oxygen at high temperature and is converted to silicon oxide. Thus, some of the silicon at the surface is consumed by this process. Imagine an array of silicon nanowires on a silicon surface. If the substrate surface were otherwise unprotected then a thermal oxidation process would oxidise both the surface of the nanowires and the surface of the substrate resulting in a configuration resembling FIG. 12(a). This configuration is similar to what would be formed in a conventional isotropic CVD process where a layer would be deposited over all surfaces. However, if the exposed surface of the substrate is first protected to prevent it from oxidising (for example, as with the embodiment describing formation of elongate structures through holes in a surface layer) the configuration would resemble FIG. 12(b). Thus, it can be seen that it is possible for a thermal oxide surrounding the nanowire and acting say as a gate dielectric to be considered as either part of the matrix or as part of the nanowire itself depending on how it is deposited and the form it takes.

In the embodiments described above, once the groups of nanowires have been encapsulated in the matrix each group has been separated from the others (in embodiments in which the matrix encapsulating one group is continuous with the matrix encapsulating an adjacent group). The invention is not however limited to this, and two or more groups of nanowires may be incorporated in a single device.

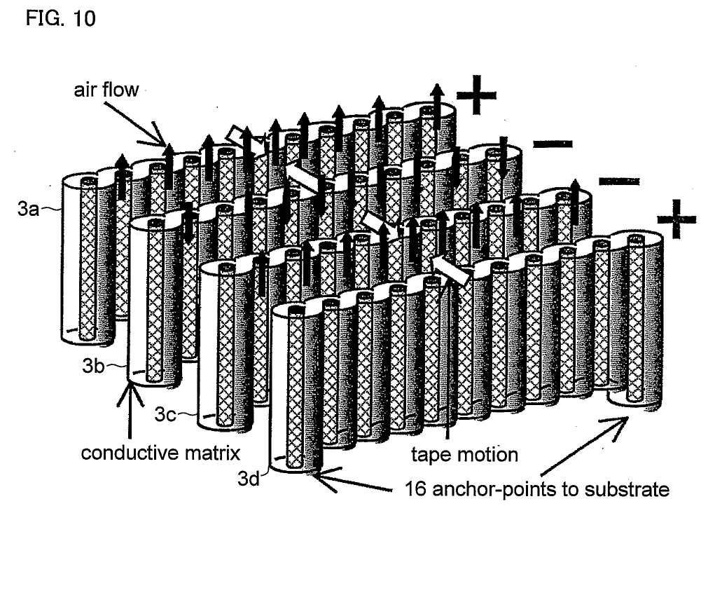

FIG. 10 shows a micro-electro-mechanical (MEM) system comprising a plurality of groups 3a-3d of nanowires 1, with each group of nanowires being encapsulated in a matrix 5. (Four groups are shown in FIG. 10, but the embodiment is not limited to this specific number of groups.) The groups of nanowires extend generally parallel to one another. The groups of encapsulated nanowires may for example be formed as described with reference to FIGS. 7(a) to 7(d).

The encapsulated groups of nanowires are, in this embodiment, not transferred to a target substrate, and the formation substrate also functions as the receiver/target substrate. Each group is adhered to the formation/target structure only at points 16 near the ends of the fins, and away from these anchor points the fins are not adhered to the substrate.

In one particular mode of operation, a dc voltage, denoted by “+” in FIG. 10 is applied across a first group 3d of nanowires, and a second dc voltage, denoted by “−” is applied across a third group 3b of nanowires. Moreover, ac voltages ac1 and ac2 are applied to fourth and second groups 3a, 3c of nanowires respectively. The ac voltages are out of phase with one another, for example by 180°. In this embodiment the matrix 5 comprises a conductive material, and application of the voltage causes the matrix, away from the anchor points 16, to move parallel to the substrate, as the polarity of the applied voltage changes. If ac1 is positive and ac2 is negative the polarity of the voltages applied to the groups of nanowires is appropriate to cause the fourth group 3a to be attracted to the third group 3b, and for the second group 3b to be attracted to the first group 3a, but for the third group 3b to be repelled by the second group 3c, as indicated by the white arrows in FIG. 10. Hence, air is squeezed out of the gap between the fourth group 3a and the third group 3b, and out of the gap between the second group 3c and the first group 3d, but air is sucked into the gap between the third group 3b and the second group 3c, as indicated by the filled black arrows in FIG. 10.

The MEM system thus provides an airflow for, for example, cooling another component. Another example of an operation mode might utilize four different ac signals where the signals applied to neighbouring groups are phase shifted by 90°. In this case, the frequency with which the groups oscillate is twice the frequency of the applied ac voltages.

The present invention allows the nanowires 1 to be formed with the requisite pattern and orientation such that they act as supports for the subsequent matrix formation to yield a high aspect ratio MEMS-type structures. The need for lithography and etching to define a structure similar to that shown in FIG. 10 is eliminated by the invention.

The invention has been described above with reference to embodiments in which nanowires are the low dimensional structures encapsulated in the matrix. The invention is not however limited to this, and may be applied with other elongate structures such as carbon nanotubes, laser diodes or light-emitting diodes (LEDs). For example, in a further embodiment an array of laser diodes or LEDs are embedded in the matrix. The matrix is used to transfer the devices to a panel used in an electronic display such as an LCD where they may be used as emission sources for optical interconnects or to provide other on-panel functionality. The matrix can optionally be used to make electrical contact to the laser diodes or LEDs or to couple light from the laser diodes or LEDs.

Moreover, the invention is not limited to elongate structures and may be applied with other low-dimensional structures such as, for example platelets. One could imagine forming a fin-type structure from a line of vertically oriented platelets—provided the plane of each platelet lies parallel to the line of platelets, and the spacing between adjacent platelets is less than twice the thickness of matrix, a fin-type structure may be formed.

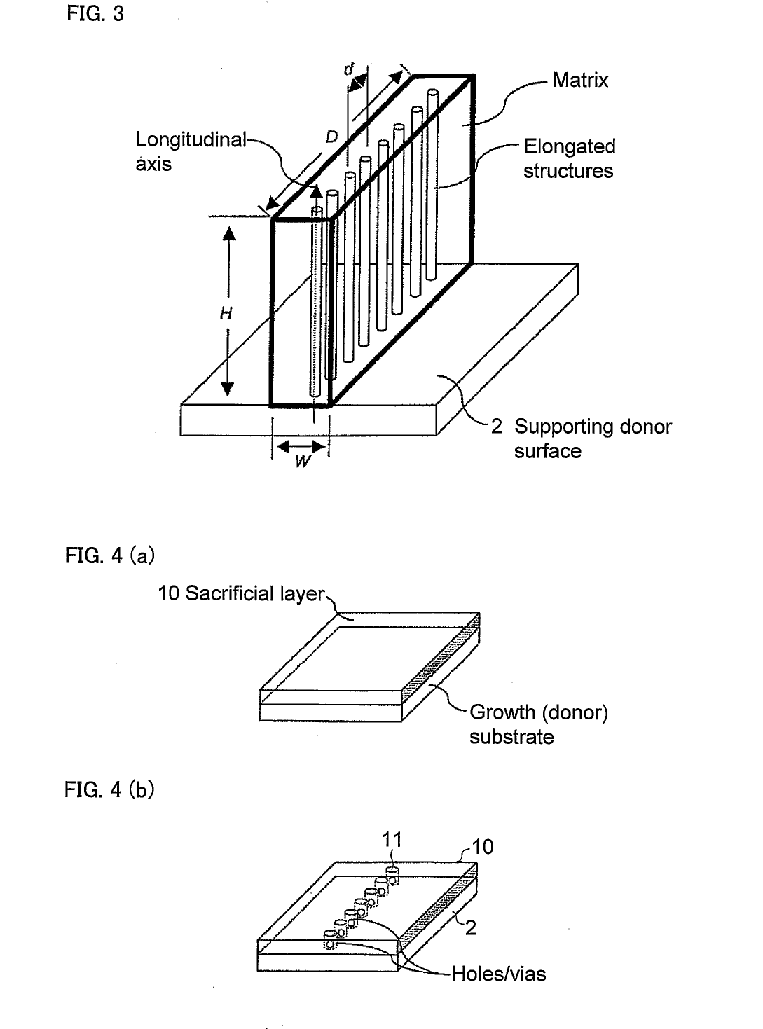

In the embodiments described above, each group of low-dimensional structures has been a linear group, in which the low-dimensional structures are arranged along a line, for example along a straight line. The invention is not limited to this, and the groups may have any suitable form. For example, each group may consist of low-dimensional structures arranged along a closed path, as shown in FIG. 2.

The low-dimensional structures in a group may be spaced regularly, or they may be spaced irregularly.

1. A method of encapsulating low dimensional structures, the method comprising:
forming a first group of low dimensional structures and a second group of low dimensional structures on a first substrate; and
encapsulating the first group of low dimensional structures and the second group of low dimensional structures in a matrix, the first group of low dimensional structures being encapsulated separately from the second group of low dimensional structures.

2. A method as claimed in claim 1 and comprising encapsulating the first and second groups of low dimensional structures such that the matrix encapsulating the first group of low dimensional structures is continuous with the matrix encapsulating the second group of low dimensional structures only near the first substrate.

3. A method as claimed in claim 1 and comprising encapsulating the first and second groups of low dimensional structures such that the matrix encapsulating the first group of low dimensional structures is not continuous with the material encapsulating the second group of low dimensional structures.

4. A method as claimed in claim 1 and comprising the further step of separating the matrix encapsulating the first group of low dimensional structures from the matrix encapsulating the second group of low dimensional structures.

5. A method as claimed in claim 3 and comprising the further step of transferring at least one of the first group of low dimensional structures and the second group of low dimensional structures to a second substrate.

6. A method as claimed in claim 3 and comprising the further step of re-orienting and/or re-positioning at least one of the first group of low dimensional structures and the second group of low dimensional structures on the first substrate.

7. A method as claimed in claim 1, wherein the spacing between the first group and the second group is greater than the maximum spacing between adjacent low dimensional structures in any of the groups.

8. A method as claimed in claim 1 wherein the low dimensional structures in each group are arranged along a respective line.

9. A method as claimed in claim 8 wherein the low dimensional structures in each group are arranged along a respective straight or substantially straight line.

10. A method as claimed in claim 1 wherein the low dimensional structures in each group are regularly spaced.

11. A method as claimed in claim 1 wherein the low dimensional structures in each group are irregularly spaced.

12. A method as claimed in claim 1 and further comprising the steps of: forming a layer over the first substrate; and defining a plurality of holes in the layer so as to expose the first substrate; and wherein the step of forming the first and second groups of low dimensional structures comprises forming each structure at a respective hole in the layer.

13. A method as claimed in claim 12 and comprising the further step of removing the layer after forming the first and second groups of low dimensional structures.

14. A method comprising: forming a layer over a first substrate;
defining a plurality of holes in the layer so as to expose the substrate;
forming a plurality of low dimensional structures over the substrate, each structure at a respective hole in the layer;
encapsulating the low dimensional structures in a matrix; and
removing the layer.

15. A method as claimed in claim 14 and comprising the further step of transferring the low dimensional structures to a second substrate.

16. A method as claimed in claim 12 wherein the layer is a silica or silicon nitride layer.

17. A method as claimed in claim 1 and comprising the further step of removing at least a portion of the matrix.

18. A method as claimed in claim 17 wherein the step of removing at least a portion of the matrix comprises planarising at least one surface of the matrix.

19. A method as claimed in claim 17 wherein the step of removing at least a portion of the matrix comprises exposing at least a portion of at least one low dimensional structure.

20. A method as claimed in claim 1 wherein forming the low dimensional structures on the first substrate comprises forming the low dimensional structures with a first substantially unidirectional orientation.

21. A method as claimed in claim 20 wherein forming the low dimensional structures on the first substrate comprises forming elongate structures with their longitudinal axes substantially perpendicular to the first substrate.

22. A method as claimed in claim 20 when dependent directly or indirectly from claim 5 or claim 15 comprising encapsulating the first and second groups of low dimensional structures such that the matrix encapsulating the first group of low dimensional structures is not continuous with the material encapsulating the second group of low dimensional structures, comprising the further step of transferring at least one of the first group of low dimensional structures and the second group of low dimensional structures to a second substrate, and wherein the transferring step comprises transferring the low dimensional structures to the second substrate with a second substantially unidirectional orientation different from the first substantially unidirectional orientation.

23. A method as claimed in claim 21 wherein the transferring step comprises transferring the elongate structures to the second substrate with their longitudinal axes substantially parallel to the first substrate,
and comprising encapsulating the first and second groups of low dimensional structures such that the matrix encapsulating the first group of low dimensional structures is not continuous with the material encapsulating the second group of low dimensional structures
and comprising the further step of transferring at least one of the first group of low dimensional structures and the second group of low dimensional structures to a second substrate.

24. A method as claimed in claim 1 wherein the step of encapsulating the low dimensional structures comprises forming at least a layer of a first encapsulant material over the low dimensional structures.

25. A method as claimed in claim 1 wherein the step of encapsulating the low dimensional structures comprises forming at least a layer of a first encapsulant material over the low dimensional structures and forming a layer of a second encapsulant material different from the first encapsulant material over the layer of the first encapsulant material.

26. A method as claimed in claim 1 wherein the step of encapsulating the low dimensional structures comprises forming at least a layer of a first encapsulant material over the low dimensional structures, and transforming at least part of the first encapsulant material to a second encapsulant material different from the first encapsulant material.

27.-34. (canceled)

35. A composite structure comprising:
a matrix; and
a plurality of low dimensional structures embedded in the matrix;
wherein the low dimensional structures are arranged along at least a line extending generally perpendicular to an axis of the low dimensional structures; and
wherein the low dimensional structures are arranged along a substantially straight line; and
wherein the low dimensional structures are substantially unidirectionally oriented; and
wherein the low dimensional structures lie substantially within a common plane, where said common plane is substantially parallel to at least one side face of the composite structure; and
wherein the low dimensional structures are substantially straight; and
wherein the matrix is a material compatible with a substantially isotropic deposition process.

36. (canceled)

37. A structure as claimed in claim 35 wherein the maximum separation between any two adjacent neighbouring structures is less than the smallest dimension of the matrix.

38. (canceled)

39. A structure as claimed in claim 35 wherein the low dimensional structures are regularly spaced.

40. A structure as claimed in claim 35 wherein the low dimensional structures are irregularly spaced.

41. A structure as claimed in claim 35 wherein the low dimensional structures are elongate structures arranged along at least a line extending generally perpendicular to the longitudinal axes of the low dimensional structures.

42. A structure as claimed in claim 35 wherein at least a portion of one or more of the low dimensional structures is not covered by the matrix.

43. A structure as claimed in claim 35 wherein at least one of the low dimensional structures is not covered by the matrix along substantially its entire length.

44. A structure as claimed in claim 35 wherein the matrix comprises at least a layer of a first encapsulant material disposed over each of the low dimensional structures.

45. A structure as claimed in claim 35 wherein the matrix comprises at least a layer of a first encapsulant material disposed over each of the low dimensional structures and a layer of a second encapsulant material different from the first encapsulant material disposed over the first encapsulant material.

46.-51. (canceled)

52. A structure as claimed in claim 42 and comprising a transistor.

53. A structure as claimed in claim 52 wherein the matrix encapsulates an intermediate portion of the low dimensional structures but does not encapsulate each end portion of the low dimensional structures; wherein first end portions of the low dimensional structures are electrically connected to a first electrical contact; wherein second end portions of the low dimensional structures are electrically connected to a second electrical contact; and wherein the matrix is electrically connected to a third electrical contact.

54. A structure as claimed in claim 35 wherein the structure is a light emissive structure.

55. A structure as claimed in claim 54 and comprising means for driving the low-dimensional structures to emit light.

56. A structure as claimed in claim 55 and comprising means for electrically driving the low-dimensional structures to emit light.

57. A structure as claimed in claim 54 wherein the encapsulant material absorbs light, in use, thereby to cause the low-dimensional structures to re-emit light.

58. A structure as claimed in claim 35 wherein the structure is a light sensing structure.

59. A structure as claimed in claim 35 wherein the structure is a photo-voltaic structure.

60. A structure as claimed in claim 58 wherein the encapsulant material is arranged to re-direct incident light onto the low-dimensional structures.

61. A structure as claimed in claim 35 wherein the structure comprises a memory device.

62. A structure as claimed in claim 61 wherein matrix comprises, in sequence: a first electrically insulating layer; a first electrically conductive layer; a second electrically insulating layer; and a second electrically conductive layer; wherein the first electrically insulating layer around a low-dimensional structure is separate from the first electrically insulating layer around an adjacent low-dimensional structure; wherein the first electrically conductive layer around a low-dimensional structure is separate from the first electrically conductive layer around an adjacent low-dimensional structure; wherein the second electrically insulating layer around a low-dimensional structure is continuous with the second electrically insulating layer around an adjacent low-dimensional structure; and wherein the second electrically conductive layer around a low-dimensional structure is continuous with the second electrically conductive layer around an adjacent low-dimensional structure.

63. A structure as claimed in claim 35 wherein the structure comprises a first group of low-dimensional structures encapsulated in a first matrix and a second group of low-dimensional structures encapsulated in a second matrix, the first group of low-dimensional structures being opposed to the second group of low dimensional structures; and wherein the first matrix and the second matrix are electrically conductive.

64. A structure as claimed in claim 35 wherein the aspect ratio of the composite structure is greater than 10:1.

65. A structure as claimed in claim 35 wherein the matrix possess properties essential to the performance of subsequent devices in which the structure is incorporated.

66. A method as claimed in claim 4 and comprising the further step of transferring at least one of the first group of low dimensional structures and the second group of low dimensional structures to a second substrate.

67. A method as claimed in claim 4 and comprising the further step of re-orienting and/or re-positioning at least one of the first group of low dimensional structures and the second group of low dimensional structures on the first substrate.

68. A method as claimed in claim 14 wherein the layer is a silica or silicon nitride layer.

69. A method as claimed in claim 14 and comprising the further step of removing at least a portion of the matrix.

70. A method as claimed in claim 14 wherein forming the low dimensional structures on the first substrate comprises forming the low dimensional structures with a first substantially unidirectional orientation.

71. A method as claimed in claim 14 wherein the step of encapsulating the low dimensional structures comprises forming at least a layer of a first encapsulant material over the low dimensional structures.

72. A method as claimed in claim 14 wherein the step of encapsulating the low dimensional structures comprises forming at least a layer of a first encapsulant material over the low dimensional structures and forming a layer of a second encapsulant material different from the first encapsulant material over the layer of the first encapsulant material.

73. A method as claimed in claim 14 wherein the step of encapsulating the low dimensional structures comprises forming at least a layer of a first encapsulant material over the low dimensional structures, and transforming at least part of the first encapsulant material to a second encapsulant material different from the first encapsulant material.

74. A method as claimed in claim 69 wherein the step of removing at least a portion of the matrix comprises planarising at least one surface of the matrix.

75. A method as claimed in claim 69 wherein the step of removing at least a portion of the matrix comprises exposing at least a portion of at least one low dimensional structure.

76. A method as claimed in claim 70 wherein forming the low dimensional structures on the first substrate comprises forming elongate structures with their longitudinal axes substantially perpendicular to the first substrate.

77. A method as claimed in claim 70 comprising the further step of transferring the low dimensional structures to a second substrate, wherein the transferring step comprises transferring the low dimensional structures to the second substrate with a second substantially unidirectional orientation different from the first substantially unidirectional orientation.

78. A method as claimed in claim 21 wherein the transferring step comprises transferring the elongate structures to the second substrate with their longitudinal axes substantially parallel to the first substrate;
and comprising the further step of separating the matrix encapsulating the first group of low dimensional structures from the matrix encapsulating the second group of low dimensional structures;
and comprising the further step of transferring at least one of the first group of low dimensional structures and the second group of low dimensional structures to a second substrate.

79. A method as claimed in claim 76 wherein the transferring step comprises transferring the elongate structures to the second substrate with their longitudinal axes substantially parallel to the first substrate;
and comprising the further step of transferring the low dimensional structures to a second substrate.

80. A structure as claimed in claim 59 wherein the encapsulant material is arranged to re-direct incident light onto the low-dimensional structures.
